(19) United States
(12) Patent Application Publication
(10) Pub. No.: US 2026/0011371 A1
(43) Pub. Date: Jan. 8, 2026

(54) MEMORY DEVICE AND METHOD OF PERFORMING A PROGRAM OPERATION

(71) Applicant: SK hynix Inc., Icheon-si Gyeonggi-do (KR)

(72) Inventors: Jae Woong KIM, Icheon-si Gyeonggi-do (KR); In Su PARK, Icheon-si Gyeonggi-do (KR); Jung Shik JANG, Icheon-si Gyeonggi-do (KR); Dong Jae JUNG, Icheon-si Gyeonggi-do (KR); Young Hwa JO, Icheon-si Gyeonggi-do (KR); Jung Dal CHOI, Icheon-si Gyeonggi-do (KR)

(73) Assignee: SK hynix Inc., Icheon-si Gyeonggi-do (KR)

(21) Appl. No.: 19/256,682

(22) Filed: Jul. 1, 2025

(30) Foreign Application Priority Data
Jul. 3, 2024 (KR) 10-2024-0087617
May 8, 2025 (KR) 10-2025-0059855

(51) Int. Cl. G11C 16/10; G11C 16/34

(52) U.S. Cl. CPC G11C 16/10; G11C 16/3459

(57) ABSTRACT

A memory device includes a memory cell array including a plurality of memory cells coupled to a word line. The memory device also includes a peripheral circuit configured to perform a program operation including a plurality of program loops including a program pulse apply operation and a verify operation. The memory device further includes control logic configured to control the peripheral circuit to determine a voltage level of fixed program pulses applied to memory cells having a same target threshold voltage based on the target threshold voltage and a number of program loops performed among the plurality of program loops, and to perform a verify operation on memory cells passing verification in a previous program loop performed prior to a current program loop being performed among the plurality of memory cells in the current program loop.

### CROSS-REFERENCE TO RELATED APPLICATIONS

The present application claims priority under 35 U.S.C. § 119(a) to Korean patent application number 10-2024-0087617 filed on Jul. 3, 2024, and Korean patent application number 10-2025-0059855 filed on May 8, 2025 in the Korean Intellectual Property Office, the entire contents of which applications are incorporated herein by reference.

### BACKGROUND

### 1. Technical Field

Various embodiments relate generally to a memory device, and more particularly, to a memory device and a method of performing a program operation by applying acceleration pulses when performing a program pulse apply operation of applying fixed program pulses to memory cells having the same target threshold voltage.

### 2. Related Art

Memory devices are classified as volatile memory devices and non-volatile memory devices. A volatile memory device stores data only when power is supplied, and the stored data is lost when the supplied power is interrupted. A non-volatile memory device does not lose data even when the supplied power is interrupted.

A memory device may perform a program operation by applying a program pulse to memory cells. As the number of threshold voltage distributions of the memory cells increases, it is necessary to further narrow down the threshold voltage distributions of the memory cells. By applying fixed program pulses with the same voltage level to the memory cells, a sharp rise in the threshold voltages of the memory cells may be prevented. A program operation of applying fixed program pulses may take longer than a program operation of applying program pulses with amplitudes increasing by a unit step. Thus, it is necessary to reduce the time required for the program operation even when the fixed program pulses are applied.

### SUMMARY

According to an embodiment, a memory device may include: a memory cell array including a plurality of memory cells coupled to a word line; a peripheral circuit configured to perform a program operation including a plurality of program loops including a program pulse apply operation of applying program pulses to the plurality of memory cells to increase threshold voltages of the plurality of memory cells, and a verify operation of detecting whether the threshold voltages of the plurality of memory cells reach a target level prior to performing the program pulse apply operation; and control logic configured to control the peripheral circuit to determine a voltage level of fixed program pulses applied to memory cells having a same target threshold voltage based on the target threshold voltage and a number of program loops performed among the plurality of program loops, and to perform a verify operation on memory cells passing verification in a previous program loop performed prior to a current program loop being performed among the plurality of memory cells in the current program loop.

According to an embodiment, a method of operating a memory device may include: performing a verify operation to detect whether threshold voltages of a plurality of memory cells coupled to a selected word line reach a target level by applying verify voltages to the plurality of memory cells; determining a voltage level of fixed program pulses to be applied to memory cells having a same target threshold voltage based on the threshold voltages and a number of program loops performed; and performing a program pulse apply operation to increase the threshold voltages of the plurality of memory cells by applying the fixed program pulses to the plurality of memory cells. The verify operation is performed on memory cells passing verification and memory cells failing the verification in a previous program loop performed prior to a current program loop being performed.

### BRIEF DESCRIPTION OF THE DRAWINGS

FIG. 1 is a block diagram illustrating a memory device according to an embodiment of the present disclosure;

FIG. 2 is a diagram illustrating a program operation performed by applying a fixed program pulse to memory cells having the same target threshold voltage;

FIG. 3 is a diagram illustrating a program operation according to an embodiment of the present disclosure;

FIG. 4 is a diagram illustrating an offset program level and an offset verify level according to an embodiment of the present disclosure;

FIG. 5 is a diagram illustrating fixed program pulses and verify voltages corresponding to a plurality of target threshold voltages according to embodiments of the present disclosure;

FIG. 6 is a flowchart illustrating a program operation according to an embodiment of the present disclosure; and

FIG. 7 is a block diagram of a data storage system including a memory system according to an embodiment of the present disclosure.

### DETAILED DESCRIPTION

Specific structural or functional descriptions of examples of embodiments in accordance with concepts which are disclosed in this specification are illustrated only to describe the examples of embodiments in accordance with the concepts and the examples of embodiments in accordance with the concepts may be carried out by various forms but the descriptions are not limited to the examples of embodiments described in this specification.

Embodiments of the present disclosure provide a memory device and a method of performing a program operation that can reduce the time required for the program operation by increasing a voltage level of a fixed program pulse applied to memory cells in an early program loop of a plurality of program loops during the program operation.

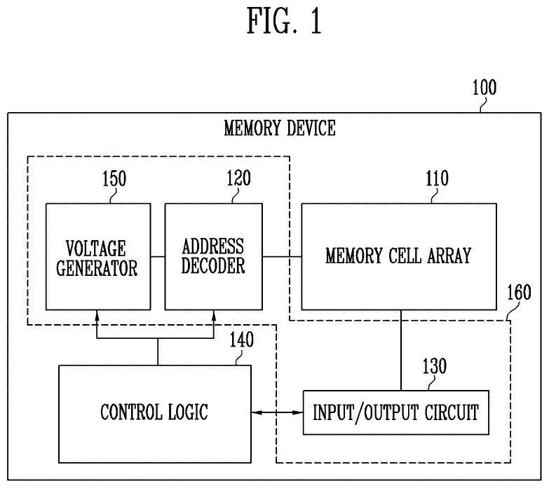

FIG. 1 is a block diagram illustrating a memory device 100 according to an embodiment of the present disclosure.

Referring to FIG. 1, the memory device 100 may store data. The memory device 100 may include a memory cell array 110 which includes memory cells storing data, an address decoder 120 which decodes column addresses, an input/output circuit 130 which transfers data to and from a device external to the memory device 100, control logic 140, and a voltage generator 150 which generates a plurality of voltages having various voltage levels.

Each of the memory cells included in the memory cell array 110 may be a single-level cell (SLC) which stores one bit of data, or a memory cell which stores multi-bit data. A memory cell storing multi-bit data may be a multi-level cell (MLC) storing two bits of data, a triple-level cell (TLC) storing three bits of data, a quad-level cell (QLC) storing four bits of data, or a penta-level cell (PLC) storing five bits of data, depending on the number of bits in the multi-bit data.

The address decoder 120 may be coupled to the memory cell array 110 via word lines. The address decoder 120 may select a word line by decoding an address received from the input/output circuit 130. The address decoder 120 may apply a voltage received from the voltage generator 150 to the selected word line. The address decoder 120 may operate in response to a control signal received from the control logic 140. For an embodiment, address decoder 120 represents an address decoder circuit.

The input/output circuit 130 may include page buffers which read data stored in the memory cells and temporarily store the data. The input/output circuit 130 may output the data stored in the page buffers to a device external to the memory device 100, or it may store data received from the external device in the page buffers and then store the data in the memory cells.

The page buffers may be coupled to the memory cells via bit lines and may store sensing data obtained by sensing threshold voltages of the memory cells during a read operation or a program operation. The sensing data may be transferred to the control logic 140.

The control logic 140 may control various operations of the memory device 100. The control logic 140 may be implemented as hardware, software, or a combination of hardware and software. For example, the control logic 140 may be a control logic circuit operating in accordance with an algorithm and/or a processor executing control logic code. The control logic 140 may generate control signals to control the address decoder 120, the input/output circuit 130, and the voltage generator 150 to perform a read operation, a program operation, and an erase operation on the memory cell array 110.

The control logic 140 may determine, based on the sensing data received from the input/output circuit 130, whether the program operation fails or not, or a verify operation passes or not. More specifically, the control logic 140 may determine that the verify operation is a verify pass when a threshold voltage of a memory cell is greater than a verify voltage. The control logic 140 may determine the program operation as a program pass when the number of memory cells which have passed verification is greater than or equal to a reference value.

The voltage generator 150 may generate voltages for operations of the memory device 100. The voltage generator 150 may include voltage regulators to generate voltages having various potentials. The voltage generator 150 may generate a program voltage, a verify voltage, and a read voltage required by the memory device 100. The voltages generated by the voltage generator 150 may be supplied to the memory cells included in the memory cell array 110 through the address decoder 120. For an embodiment, voltage generator 150 represents a voltage generator circuit.

In an embodiment of the present disclosure, the address decoder 120, the input/output circuit 130, and the voltage generator 150 may be included in or collectively referred to as a peripheral circuit 160. The control logic 140 may control the peripheral circuit 160 such that operations are performed on the memory cells included in the memory cell array 110.

In an embodiment of the present disclosure, the control logic 140 may control the peripheral circuit 160 to perform a program operation on the memory cells. The peripheral circuit 160 may perform a program pulse apply operation of applying program pulses to the memory cells to increase threshold voltages, and a verify operation to detect whether the threshold voltages of the memory cells have reached target levels.

The control logic 140 may maintain a constant voltage level of the program pulses applied to the memory cells having the same target threshold voltage while a plurality of program loops including a program pulse apply operation and a verify operation are performed. A program pulse having a constant voltage level applied to the memory cells while the plurality of program loops are performed may be referred to as a fixed program pulse.

The control logic 140 may perform a verify operation on memory cells prior to applying the fixed program pulses to the memory cells. The control logic 140 may control the peripheral circuit 160 such that a program inhibit voltage may be applied to memory cells having a threshold voltage greater than a target threshold voltage based on the results of the verify operation. The results of the verify operation may be stored in the page buffers included in the input/output circuit 130. Data indicating whether the memory cells pass verification may be stored in latch circuits included in the page buffers.

The control logic 140 may reset the page buffers storing the result of the verify operation performed in the previous program loop prior to performing the verify operation included in each of the plurality of program loops. In response to resetting of the page buffers, the latch circuits storing the data indicating whether the memory cells have passed verification may be initialized.

A verify operation performed before a fixed program pulse is applied may be performed on all memory cells which are subject to a program operation. All memory cells which are subject to the program operation may include memory cells which have already passed verification and memory cells which have not yet passed the verification in the previous program loop performed prior to the program loop currently being performed.

The control logic 140 may determine a voltage level of the fixed program pulses which are applied to memory cells having the same target threshold voltage based on the target threshold voltages and the number of program loops which have already been performed in the plurality of program loops. The control logic 140 may increase the voltage level of the fixed program pulses in a first program loop or a predetermined number of program loops from the first program loop of the plurality of program loops. As the voltage level of the fixed program pulses increases, programing speed may be increased, thereby reducing the overall time taken to perform the program operation.

The control logic 140 may decrease the level of the verify voltages in response to an increase in the voltage level of the fixed program pulses. As the number of verify-passed memory cells is increased in response to the decreased level of the verify voltages, the increase in the threshold voltage of the verify-passed memory cells may be restricted by the fixed program pulses with the increased voltage level.

According to an embodiment of the present disclosure, the voltage level of the fixed program pulses is increased in earlier program loops to increase the program speed, and fewer memory cells are overprogrammed in the remaining program loops in which the voltage level of the fixed program pulses is fixed at a level determined based on the target threshold voltage, so that the threshold voltage distribution of the memory cells may be kept narrow.

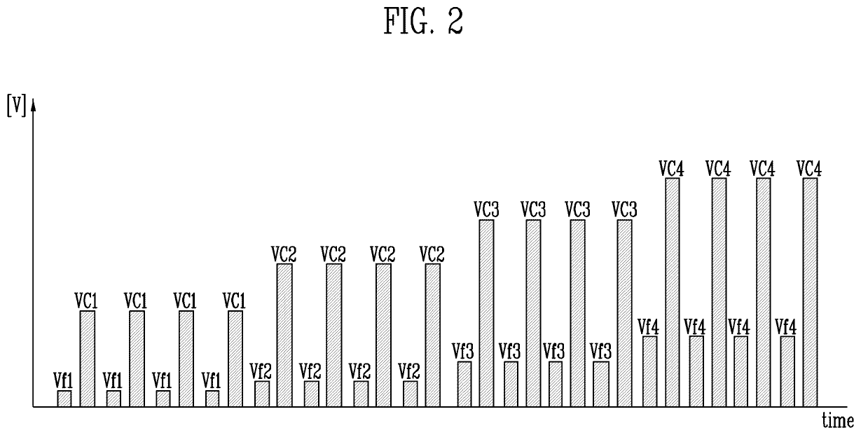

FIG. 2 is a diagram illustrating a program operation performed by applying fixed program pulse to memory cells having the same target threshold voltage.

Referring to FIG. 2, fixed program pulses having a constant voltage level may be applied to memory cells having the same target threshold voltage during a plurality of program loops. Prior to the application of the fixed program pulses, a verify operation may be performed on memory cells. In FIG. 2, the horizontal axis represents time and the vertical axis represents the magnitude of a pulse. For ease of explanation, it may be assumed that the memory cells in FIG. 2 are MLCs with two bits of data stored in one memory cell, and that four fixed program pulses are applied to cause threshold voltages of the memory cells to reach target levels.

The plurality of memory cells coupled to a selected word may be programmed in order of ascending target threshold voltages. First fixed program pulses VC1 may be applied to first memory cells having a first level as a target threshold voltage, second fixed program pulses VC2 may be applied to second memory cells having a second level as a target threshold voltage, third fixed program pulses VC3 may be applied to third memory cells having a third level as a target threshold voltage, and fourth fixed program pulses VC4 may be applied to fourth memory cells having a fourth level as a target threshold voltage.

The control logic 140 may control the peripheral circuit 160 such that a first verify voltage Vf1 may be applied before the first fixed program pulses VC1 are applied, and a second verify voltage Vf2 may be applied before the second fixed program pulses VC2 are applied. Similarly, the control logic 140 may control the peripheral circuit 160 such that a third verify voltage Vf3 may be applied before the third fixed program pulses VC3 are applied, and a fourth verify voltage Vf4 may be applied before the fourth fixed program pulses VC4 are applied.

Memory cells which are subject to a verify operation may include both memory cells which pass verification and memory cells which fail the verification in a previous program loop performed prior to a current program loop being performed. The control logic 140 may determine memory cells to which a program inhibit voltage is applied while fixed program pulses are applied, based on a result of a program operation included in the current program loop. According to an embodiment of the present disclosure, a program inhibit voltage might not be applied to memory cells which even have passed verification in the previous program loop while the fixed program pulses are applied, based on the result of the verify operation included in the current program loop. That is, the control logic 140 determines whether to apply the program inhibit voltage to the memory cells based solely on the result of the verify operation included in the current program loop.

In FIG. 2, for ease of explanation, when the number of times the fixed program pulses are applied is four, the control logic 140 determines a program operation pass based on the number of memory cells whose threshold voltages have reached the target level. The time taken for the program operation of applying fixed program pulses with a constant voltage level to the memory cells is greater than the time taken for the program operation of applying program pulses with a unit voltage magnitude increase in each program loop. As the time required for the program operation increases, the probability of a retention phenomenon where a threshold voltage distribution of programmed memory cells is widened is increased, and the program performance may be reduced.

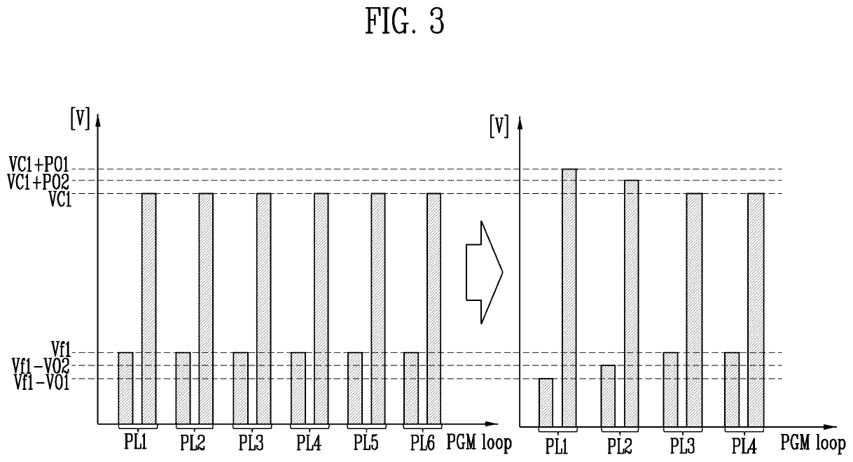

FIG. 3 is a diagram illustrating a program operation according to an embodiment of the present disclosure.

Referring to FIG. 3, a program operation may be performed such that fixed program pulses having a constant voltage level are applied to memory cells having the same target threshold voltage while a plurality of program loops are performed. In some program loops of the plurality of program loops, the voltage level of the fixed program pulses applied to the memory cells and the level of the verify voltages may change. In FIG. 3, a case in which the voltage level of the fixed program pulses and the level of the verify voltages are constant may be compared to a case in which the voltage level of the fixed program pulses and the level of the verify voltages are changed. As shown in FIG. 3, the first fixed program pulses VC1 and the first verify voltage Vf1 corresponding to a first target threshold voltage are applied to the memory cells. In FIG. 3, for ease of explanation, it may be assumed that six program loops are performed when the voltage levels of the fixed program pulses and the verify voltages are constant, and four program loops are performed when the voltage levels of the fixed program pulses and the verify voltages are changed. In FIG. 3, the horizontal axis represents the program loops and the vertical axis represents the voltage levels.

In an embodiment of the present disclosure, the control logic 140 may determine a voltage level of fixed program pulses applied to memory cells having the same target threshold voltage based on the target threshold voltage and the number of program loops which have already been performed among the plurality of program loops. The voltage level of the fixed program pulses may be a sum of a base program level and an offset program level. The control logic 140 may determine the base program level based on the target threshold voltage, and it may determine the offset program level based on the number of program loops performed.

In FIG. 3, the control logic 140 determines the base program level to be VC1 based on the first target threshold voltage. The base program level remains constant when the target threshold voltage is the same. When a first program loop PL1 is performed, the control logic 140 may determine the offset program level as a first offset program level PO1 because the number of program loops which have already been performed is zero. When a second program loop PL2 is performed, the control logic 140 may determine the offset program level to be a second offset program level PO2 because one program loop has already been performed.

The offset program level may be reduced as the number of program loops which have already been performed increases. The control logic 140 may set the first offset program level PO1 to be greater than the second offset program level PO2. In FIG. 3, VC1+PO1, which is a voltage level of fixed program pulses applied to the memory cells when the first program loop PL1 is performed, is greater than VC1+PO2, which is a voltage level of fixed program pulses applied to the memory cells when the second program loop PL2 is performed.

The control logic 140 may set the offset program level to zero when the number of program loops which have already been performed is two or more. In a third program loop PL3 and a fourth program loop PL4, the voltage level of the fixed program pulses applied to the memory cells is kept equal to VC1. In the first program loop PL1 and the second program loop PL2, the program speed is increased by the offset program level to thereby reduce the time required for the program operation, and in the third program loop PL3 and the fourth program loop PL4, fixed program pulses having a constant voltage level are applied to prevent the memory cells from being overprogrammed.

In response to an increase in the voltage level of the fixed program pulses, the control logic 140 may decrease the level of the verify voltages. The level of the verify voltages may be a difference between the base verify level and the offset verify level. The control logic 140 may determine the base verify level based on the target threshold voltage, and it may determine the offset verify level based on the number of program loops performed.

In FIG. 3, the control logic 140 determines the base verify level as Vf1 based on the first target threshold voltage. The base verify level remains constant when the target threshold voltage is the same. When the first program loop PL1 is performed, the control logic 140 may determine the offset verify level to be a first offset verify level VO1 because the number of program loops which have already been performed is zero. When the second program loop PL2 is performed, the control logic 140 may determine the offset verify level as a second offset verify level VO2 because the number of program loops which have already been performed is one.

As the number of program loops performed increases, the offset verify level may be decreased. The control logic 140 may set the first offset program level PO1 to be greater than the second offset program level PO2. In FIG. 3, Vf1−VO1 which is a level of a verify voltage applied to the memory cells during the first program loop PL1 is lower than Vf1−VO2 which is a level of a verify voltage applied to the memory cells during the second program loop PL2.

The control logic 140 may set the offset verify level to zero when the number of program loops which have already been performed is two or more. In the third program loop PL3 and the fourth program loop PL4, the level of the verify voltage applied to the memory cells remains the same as Vf1. In the first program loop PL1 and the second program loop PL2, because the program speed is increased by the offset program level, a verify operation is performed by lowering the level of the verify voltage to prevent overprogramming. Because the offset program level is zero in the third program loop PL3 and the fourth program loop PL4, the control logic 140 may control the peripheral circuit 160 to restore the level of the verify voltage to Vf1 so that the verify operation may be performed.

In FIG. 3, when the voltage level of the fixed program pulses is constant for the threshold voltages of the memory cells to reach the first target threshold voltage, six program loops from the first program loop PL1 to a sixth program loop PL6 need to be performed, whereas when the voltage level of the fixed program pulses is increased in earlier program loops, only four program loops from the first program loop PL1 to the fourth program loop PL4 need to be performed for the threshold voltages of the memory cells to reach the first target threshold voltage. Similarly, for a plurality of target threshold voltages, the time for the threshold voltages of the memory cells to reach target levels is reduced, and thus, the overall duration of the program operation may be reduced.

For ease of description, FIG. 3 illustrates two offset program levels and two offset verify levels, but the numbers of offset program levels and offset verify levels may vary. FIG. 3 shows only one embodiment, and the number of program loops which have already been performed as a basis for determining the offset program level and the offset verify level may vary.

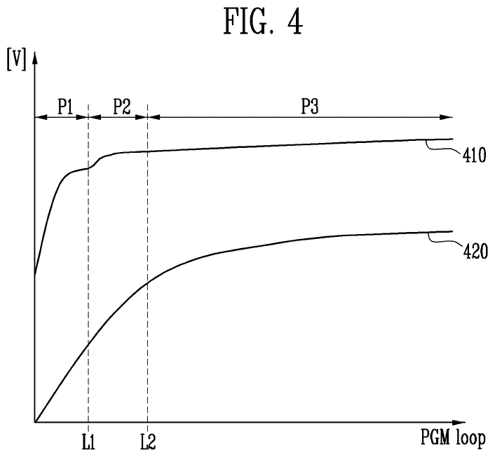

FIG. 4 is a diagram illustrating an offset program level and an offset verify level according to embodiments of the present disclosure.

FIG. 4 shows a threshold voltage distribution of memory cells over the progression of program loops. In FIG. 4, 410 indicates a voltage to the right of the threshold voltage distribution corresponding to a target threshold voltage, and 420 indicates a voltage to the left of the threshold voltage distribution corresponding to the target threshold voltage. The difference between 410 and 420 may represent the width of the threshold voltage distribution. In FIG. 4, the horizontal axis may represent the number of program loops performed, and the vertical axis may represent threshold voltages of memory cells. In FIG. 4, for ease of explanation, the plurality of program loops may be divided into a first section P1, a second section P2, and a third section P3. The first section P1 may be assumed to be a section in which L1 program loops are performed, the second section P2 may be a section in which the number of program loops performed is from L1+1 to L2, and the remaining section may be assumed to be the third section P3. In the description of FIG. 4, portions which are redundant with FIG. 3 may be omitted.

In FIG. 4, the control logic 140 may determine the voltage level of the fixed program pulses during the first section P1 as VC1+PO1, determine the voltage level of the fixed program pulses during the second section P2 as VC1+PO2, and determine the voltage level of the fixed program pulses during the third section P3 as VC1. Because the voltage level of the fixed program pulses applied to the memory cells is the highest during the first section P1, the threshold voltages of the memory cells are raised most sharply during the first section P1. During the second section P2, the threshold voltages of the memory cells rise more rapidly than during the third section P3, and during the third section P3, the threshold voltages of the memory cells rise most gradually.

The control logic 140 may decrease the offset program level as the width of the threshold voltage distribution decreases. In FIG. 4, the width of the threshold voltage distribution corresponding to the target threshold voltage is the greatest during the first section P1. An offset program voltage PO1 in the first section P1 is greater than an offset program voltage PO2 in the second section P2. An offset program voltage in the third section P3 may be zero.

The control logic 140 may determine the offset program level to be PO1 in response to the width of the threshold voltage distribution being greater than or equal to a first reference value. The control logic 140 may determine the offset program level as PO2 in response to the width of the threshold voltage distribution exceeding the first reference value and below the second reference value. The control logic 140 may determine the offset program level as zero in response to the width of the threshold voltage distribution exceeding a second reference value. The offset program level may be determined based on the number of program loops performed or the width of the threshold voltage distribution corresponding to the target threshold voltage.

The control logic 140 may decrease the level of the verify voltages in response to an increase in the voltage level of the fixed program pulses. In FIG. 4, the control logic 140 may determine the level of the verify voltages to be Vf1−VO1 during the first section P1, determine the level of the verify voltages to be Vf1−VO2 during the second section P2, and determine the level of the verify voltages to be Vf1 during the third section P3. Because the voltage level of the fixed program pulses applied to the memory cells is the highest during the first section P1, the threshold voltages of the memory cells are most rapidly increased during the first section P1. The verify voltage level of the memory cells may be the lowest during the first section P1 Because the memory cells are most likely to be overprogrammed during the first section P1. During the second section P2, the program speed is lower than in the first section P1, so the verify voltage level in the second section P2 is greater than the verify voltage level in the first section P1. During the third section P3, the threshold voltages of the memory cells are most gently increased, so the verify voltage in the third section P3 may be the highest.

The control logic 140 may decrease the offset verify level as the width of the threshold voltage distribution decreases. In FIG. 4, the width of the threshold voltage distribution corresponding to the target threshold voltage is the greatest during the first section P1. An offset verify voltage VO1 in the first section P1 is larger than an offset verify voltage VO2 in the second section P2. An offset verify voltage of the third section P3 may be zero.

The control logic 140 may determine the offset verify level to be VO1 in response to the width of the threshold voltage distribution being greater than or equal to the first reference value. The control logic 140 may determine the offset verify level as VO2 in response to the width of the threshold voltage distribution exceeding the first reference value and less than or equal to the second reference value. The control logic 140 may determine the offset verify level to be zero in response to the width of the threshold voltage distribution exceeding the second reference value. The offset verify level may be determined based on the number of program loops performed or the width of the threshold voltage distribution corresponding to the target threshold voltage.

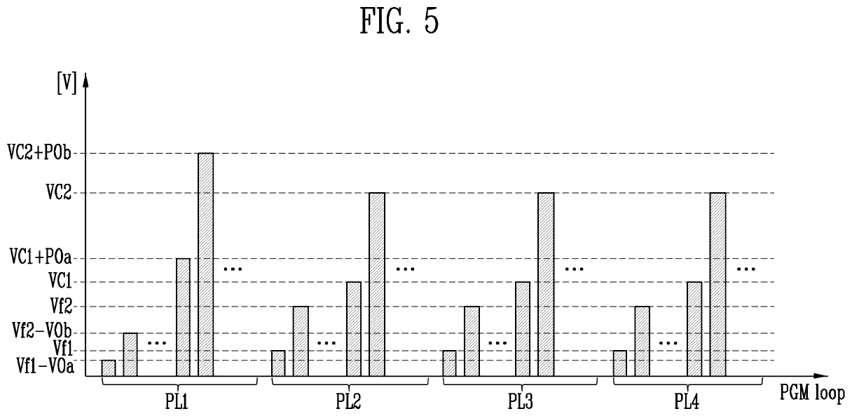

FIG. 5 is a diagram illustrating fixed program pulses and verify voltages corresponding to a plurality of target threshold voltages according to embodiments of the present disclosure.

Referring to FIG. 5, fixed program pulses and verify voltages corresponding to a plurality of target threshold voltages may be applied to memory cells in a single program loop. For ease of description, it may be assumed that the offset program level and the offset verify level are positive only in the first program loop PL1, and that both the offset program level and the offset verify level are zero in the remaining program loops. In FIG. 5, the horizontal axis may represent the number of program loops performed, and the vertical axis may represent a voltage level.

In FIG. 5, when one program loop is performed, n fixed program pulses may be applied to the memory cells after n verify voltages are applied. In FIG. 5, the overhead time for switching between a verify operation and a program pulse apply operation when a program loop is performed may be minimized. The order in which the n verify voltages and the n fixed program pulses are applied to the memory cells may be determined by the retention characteristics of the threshold voltages. A verify voltage and a fixed program pulse corresponding to the threshold voltage which is the most vulnerable to retention may be applied lastly. The n verify voltages correspond to the n fixed program pulses, respectively, and a base program level and a base verify level are the same for memory cells with the same target threshold voltage.

The control logic 140 may determine the base program level and the offset program level based on the target threshold voltage. The control logic 140 may increase the base program level and the offset program level as the target threshold voltage increases.

In FIG. 5, the control logic 140 may determine the base program level as VC1 based on the first target threshold voltage, and it may determine the offset program level as POa in the first program loop PL1. The control logic 140 may determine the base program level as VC2 based on the second target threshold voltage, and it may determine the offset program level as POb in the first program loop PL1. Because the first target threshold voltage is smaller than the second target threshold voltage, POa may be smaller than POb.

While FIG. 5 shows only one embodiment, the number of target threshold voltages may be two or more. Similarly, larger target threshold voltages may increase the base program level and the offset program level corresponding to the target threshold voltages.

In FIG. 5, the control logic 140 may determine a base verify level as Vf1 based on the first target threshold voltage, and it may determine an offset verify level as VOa in the first program loop PL1. The control logic 140 may determine the base verify level as Vf2 based on the second target threshold voltage, and it may determine the offset verify level as VOb in the first program loop PL1. Because the first target threshold voltage is smaller than the second target threshold voltage, VOa may be smaller than VOb.

While FIG. 5 shows only one embodiment, the number of target threshold voltages may be two or more. Similarly, larger target threshold voltages may increase the base verify level and offset verify level corresponding to the target threshold voltages.

In FIG. 5, it is assumed that the offset program level and the offset verify level are positive in the first program loop PL1 only, but because this is only an embodiment, there may be a plurality of program loops with a positive offset program level and a positive offset verify level. Further, the offset program level and the offset verify level between different program loops may be different.

In other embodiments of the present disclosure, the control logic 140 may determine the offset program levels corresponding to the plurality of target threshold voltages to be the same when one program loop is performed. For example, POa and POb may be the same. Similarly, the control logic 140 may determine the offset verify levels corresponding to the plurality of target threshold voltages to be the same when one program loop is performed. For example, VOa and VOb may be the same.

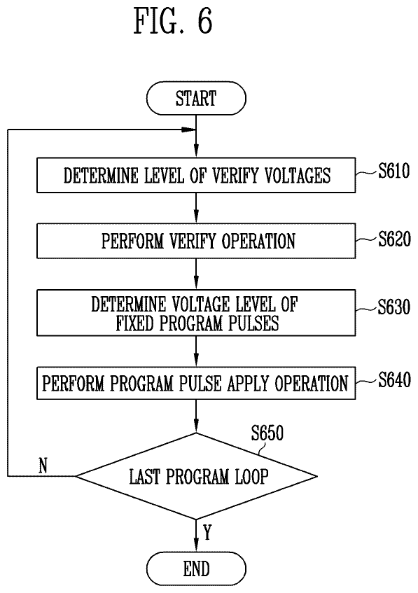

FIG. 6 is a flowchart illustrating a program operation according to an embodiment of the present disclosure.

Referring to FIG. 6, a memory device may perform a program operation including a plurality of program loops including a program pulse apply operation to apply program pulses to memory cells to increase threshold voltages of the memory cells, and a verify operation to detect whether the threshold voltages of the memory cells reach a target level prior to performing the program pulse apply operation. While the plurality of program loops are being performed, the memory device may apply fixed program pulses having a voltage level determined based on the number of program loops which have already been performed to memory cells having the same target threshold voltage, and the memory device may apply a program inhibit voltage to memory cells determined based on the result of the verify operation while the program pulse apply operation is being performed. According to an embodiment of the present disclosure, the speed of the program operation may be improved by increasing the voltage level of the fixed program pulses of the initial program loops of the plurality of program loops.

At step S610, control logic, such as a control logic circuit or device, may determine a level of verify voltages to be applied to memory cells having the same target threshold voltage based on the target threshold voltage and the number of program loops which have already been performed. The level of the verify voltages includes a base verify level and an offset verify level. The control logic may determine the base verify level based on the target threshold voltage and determine the offset verify level based on the number of program loops performed or a width of the threshold voltage distribution corresponding to the target threshold voltage.

The control logic may determine a difference between the base verify level and the offset verify level as the level of the verify voltages corresponding to the target threshold voltage. The control logic may decrease the offset verify level as the number of program loops performed increases or the width of the threshold voltage distribution decreases. In embodiments of the present disclosure, when there are a plurality of target threshold voltages, the control logic may increase the base verify level and the offset verify level as the target threshold voltage increases.

At step S620, the control logic may control a peripheral circuit to apply the verify voltages to a plurality of memory cells coupled to a selected word line to perform a verify operation to detect whether threshold voltages of the plurality of memory cells reach a target level. The level of the verify voltages applied to the plurality of memory cells is determined in step S610.

The control logic may perform a verify operation on memory cells which pass verification and memory cells which fail verification in a previous program loop performed prior to the current program loop being performed. In other words, the verify operation is performed on all memory cells to which fixed program pulses are to be applied in the current program loop regardless of the verify result of the previous program loop. Based on the result of the verify operation, the control logic may determine program-inhibit memory cells to which a program inhibit voltage is to be applied among the plurality of memory cells.

At step S630, the control logic may determine a voltage level of fixed program pulses to be applied to the memory cells having the same target threshold voltage based on the target threshold voltage and the number of program loops performed. The voltage level of the fixed program pulses includes a base program level and an offset program level. The control logic may determine the base program level based on the target threshold voltage, and it may determine the offset program level based on the number of program loops performed or the width of the threshold voltage distribution corresponding to the target threshold voltage.

The control logic may determine the sum of the base program level and the offset program level as the voltage level of fixed program pulses corresponding to the target threshold voltage. The control logic may decrease the offset program level as the number of program loops performed increases and/or the width of the threshold voltage distribution decreases. In embodiments of the present disclosure, when there are a plurality of target threshold voltages, the control logic may increase the base program level and the offset program level as the target threshold voltage increases.

At step S640, the control logic may control the peripheral circuit to perform a program pulse apply operation of applying the fixed program pulses to the plurality of memory cells to increase the threshold voltages of the plurality of memory cells. The voltage level of the fixed program pulses applied to the plurality of memory cells is determined at step S630.

While the fixed program pulses are being applied, the control logic may apply the program inhibit voltage to the program-inhibit memory cells determined based on the results of the verify operation. The program inhibit voltage may be applied through bit lines of the program-inhibit memory cells.

At step S650, the control logic may detect whether the current program loop being performed is the last program loop. When the current program loop is the last program loop, the control logic may terminate the program operation. When the current program loop is not the last program loop, the control logic may increment a program loop count value by one (1) and perform step S610 again.

The descriptions of the steps in FIG. 6 may correspond to the descriptions made with reference to FIGS. 1 to 5.

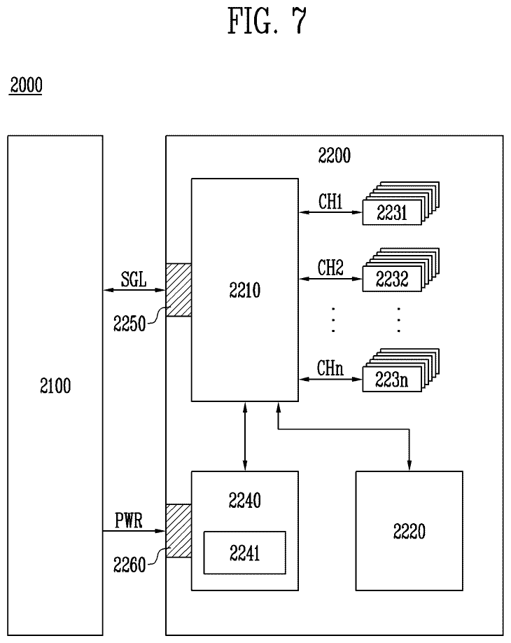

FIG. 7 is a block diagram illustrating a data storage system 2000 including a memory system according to an embodiment of the present disclosure.

Referring to FIG. 7, the data storage system 2000 may include a host device 2100 and a sold-state drive (SSD) 2200.

The SSD 2200 may include a controller 2210, a buffer memory device 2220, non-volatile memory components 2231 to 223n, a power supply 2240, a signal connector 2250, and a power connector 2260. The SSD 2200 may include the memory device 100 described in FIGS. 1 to 5.

The buffer memory device 2220 may temporarily store data to be stored in the plurality of non-volatile memory components 2231 to 223n. In addition, the buffer memory device 2220 may temporarily store data read from the non-volatile memory components 2231 to 223n. The data temporarily stored in the buffer memory device 2220 may be transferred to the host device 2100 or the non-volatile memory components 2231 to 223n in response to control of the controller 2210.

The non-volatile memory components 2231 to 223n may serve as storage media of the SSD 2200. The non-volatile memory components 2231 to 223n may be coupled to the controller 2210 through a plurality of channels CH1 to CHn, respectively. One or more non-volatile memory components may be coupled to one channel. Non-volatile memory components coupled to one channel may be coupled to the same signal bus or data bus.

The controller 2210 may perform general operations of the SSD 2200. According to an embodiment of the present disclosure, the controller 2210 may control the SSD 2200 to perform a program operation including a plurality of program loops including a program pulse apply operation of applying program pulses to a plurality of memory cells to increase threshold voltages of the plurality of memory cells and a verify operation of detecting whether the threshold voltages of the plurality of the memory cells reach target levels before performing the program pulse apply operation. The controller 2210 may control the SSD 2200 such that fixed program pulses may be applied to memory cells having the same target threshold voltage while the plurality of program loops are being performed, and a program inhibit voltage may be applied to memory cells determined based on a result of the verify operation while the program pulse apply operation is being performed.

The controller 2210 may determine the sum of the basic program level determined based on the target threshold voltage and the offset program level determined based on the number of program loops performed or the width of the threshold voltage distribution corresponding to the target threshold voltage as the voltage level of the fixed program pulses. The controller 2210 may determine the offset program level to be positive when the number of program loops performed is less than or equal to a reference number or when the width of the threshold voltage distribution is greater than a reference width. Accordingly, the program speed may be increased in initial program loops among the plurality of program loops.

The controller 2210 may determine the difference between the basic verify level determined based on the target threshold voltage and the offset verify level determined based on the number of program loops performed or the width of the threshold voltage distribution corresponding to the target threshold voltage as a level of a verify voltage. The controller 2210 may determine the offset verify level to be positive when the number of program loops performed is less than or equal to the reference number or when the width of the threshold voltage distribution is greater than the reference width. Because the level of the verify voltage decreases in response to an increase in the magnitudes of the fixed program pulses, the possibility of overprogramming the memory cells may be reduced.

In the embodiment of the present disclosure, the time required for a program operation may be reduced by raising the voltage level of the fixed program pulses in the initial program loops and lowering the level of the verify voltage. Because the program time is reduced, the program performance of the SSD 2200 may be improved.

The power supply 2240 may supply power PWR which is input through the power connector 2260 to the inside of the SSD 2200. The power supply 2240 may include an auxiliary power supply 2241. The auxiliary power supply 2241 may supply power such that the SSD 2200 may be terminated normally when a sudden power off occurs. The auxiliary power supply 2241 may include large-capacity capacitors which charge the power PWR.

The controller 2210 may exchange signals SGL with the host device 2100 through the signal connector 2250. The signals SGL may include commands, addresses, and data. The signal connector 2250 may be configured as various types of connectors according to an interfacing method of the host device 2100 and the SSD 2200.

According to the present disclosure, a memory device and a method of performing a program operation that can reduce the time taken for threshold voltages of memory cells to reach a target level by increasing a voltage level of fixed program pulses and applying the fixed program pulses to the memory cells during initial program loops.

It will be apparent to those skilled in the art that various modifications can be made to the above-described embodiments without departing from the spirit or scope of the present teachings. Thus, it is intended that the present invention cover all such modifications provided they come within the scope of the appended claims and their equivalents.

What is claimed is:

1. A memory device, comprising:
a memory cell array including a plurality of memory cells coupled to a word line;
a peripheral circuit configured to perform a program operation including a plurality of program loops including a program pulse apply operation of applying program pulses to the plurality of memory cells to increase threshold voltages of the plurality of memory cells, and a verify operation of detecting whether the threshold voltages of the plurality of memory cells reach a target level prior to performing the program pulse apply operation; and
control logic configured to control the peripheral circuit to determine a voltage level of fixed program pulses applied to memory cells having a same target threshold voltage based on the target threshold voltage and a number of program loops performed among the plurality of program loops, and to perform a verify operation on memory cells passing verification in a previous program loop performed prior to a current program loop being performed among the plurality of memory cells in the current program loop.

2. The memory device of claim 1, wherein the voltage level of the fixed program pulses is determined as a sum of a base program level and an offset program level, and
wherein the control logic is configured to determine the base program level based on the target threshold voltage and determine the offset program level based on the number of program loops performed.

3. The memory device of claim 2, wherein the control logic is configured to decrease the offset program level in response to an increase in the number of program loops performed.

4. The memory device of claim 2, wherein the control logic is configured to determine the offset program level based on a width of a threshold voltage distribution corresponding to the target threshold voltage.

5. The memory device of claim 4, wherein the control logic is configured to decrease the offset program level as the width of the threshold voltage distribution decreases.

6. The memory device of claim 2, wherein the control logic is configured to increase both the base program level and the offset program level in response to an increase in the target threshold voltage.

7. The memory device of claim 1, wherein a level of a verify voltage corresponding to the target threshold voltage is determined as a difference between a base verify level and an offset verify level, and
wherein the control logic is configured to determine the base verify level based on the target threshold voltage and determine the offset verify level based on the number of program loops performed.

8. The memory device of claim 7, wherein the control logic is configured to decrease the offset verify level in response to an increase in the number of program loops performed.

9. The memory device of claim 7, wherein the control logic is configured to determine the offset verify level based on a width of a threshold voltage distribution corresponding to the target threshold voltage.

10. The memory device of claim 9, wherein the control logic is configured to decrease the offset verify level as the width of the threshold voltage distribution decreases.

11. The memory device of claim 7, wherein the control logic is configured to increase both the base verify level and the offset verify level in response to an increase in the target threshold voltage.

12. A method of operating a memory device, the method comprising:
performing a verify operation to detect whether threshold voltages of a plurality of memory cells coupled to a selected word line reach a target level by applying verify voltages to the plurality of memory cells;
determining a voltage level of fixed program pulses to be applied to memory cells having a same target threshold voltage based on the threshold voltages and a number of program loops performed; and
performing a program pulse apply operation to increase the threshold voltages of the plurality of memory cells by applying the fixed program pulses to the plurality of memory cells,
wherein the verify operation is performed on memory cells passing verification and memory cells failing the verification in a previous program loop performed prior to a current program loop being performed.

13. The method of claim 12, wherein levels of the verify voltages comprises a base verify level and an offset verify level, and
wherein performing the verify operation comprises:
determining the base verify level based on the target threshold voltage;
determining the offset verify level based on the number of program loops performed or a width of a threshold voltage distribution corresponding to the target threshold voltage; and
determining a difference between the base verify level and the offset verify level as the level of the verify voltages corresponding to the target threshold voltage.

14. The method of claim 13, wherein determining the offset verify level comprises decreasing the offset verify level as the number of program loops performed increases or the width of the threshold voltage distribution decreases.

15. The method of claim 13, wherein the base verify level and the offset verify level increase as the target threshold voltage increases.

16. The method of claim 12, wherein the voltage level of the fixed program pulses includes a base program level and an offset program level, and
wherein determining the voltage level of the fixed program pulses comprises:
determining the base program level based on the target threshold voltage;
determining the offset program level based on the number of program loops performed or a width of a threshold voltage distribution corresponding to the target threshold voltage; and
determining a sum of the base program level and the offset program level as the voltage level of the fixed program pulses corresponding to the target threshold voltage.

17. The method of claim 16, wherein determining the offset program level comprises decreasing the offset program level as the number of program loops performed increases or the width of the threshold voltage distribution decreases.

18. The method of claim 16, wherein the base program level and the offset program level increase as the target threshold voltage increases.

19. The method of claim 12, wherein performing the program pulse apply operation comprises applying a program inhibit voltage to memory cells determined based on a result of the verify operation when the fixed program pulses are applied.
